(19) United States
(12) Patent Application Publication
(10) Pub. No.: US 2026/0040997 A1
(43) Pub. Date: Feb. 5, 2026

(54) MICROELECTRONIC DEVICE PACKAGE WITH INTEGRATED PASSIVE COMPONENT DIE AND SEMICONDUCTOR DEVICE DIE

(71) Applicant: Texas Instruments Incorporated, Dallas, TX (US)

(72) Inventors: Jonathan Andrew Montoya, Dallas, TX (US); Makarand Ramkrishna Kulkami, Plano, TX (US); Jie Chen, Plano, TX (US); Jonathan Noquil, Plano, TX (US)

(21) Appl. No.: 18/791,372

(22) Filed: Jul. 31, 2024

(51) Int. Cl. H01L 25/16; H01L 23/00; H01L 23/13; H01L 23/31; H01L 23/495; H01L 23/498; H01L 25/00; H01L 29/94

(52) U.S. Cl. CPC H01L 25/16; H01L 23/13; H01L 24/14; H01L 24/16; H01L 24/81; H01L 23/3107; H01L 23/49534; H01L 23/49822; H01L 25/50; H01L 2224/1403; H01L 2224/16145; H01L 2224/16225; H01L 2224/16245; H01L 2224/81935; H01L 2224/81986; H10D 1/665

(57) ABSTRACT

A described example includes: a passive component die mounted to a device side surface of a semiconductor device die, and extending away from the device side surface of the semiconductor device die; the semiconductor device die and the passive component die flip chip mounted to a device mounting surface of a package substrate including a cavity extending into the package substrate from the device mounting surface of the package substrate, the cavity in a position corresponding to the passive component die, the passive component die extending into the cavity of the package substrate, and the package substrate having terminals on a board side surface; and mold compound covering the semiconductor device die, the passive component die, and the device mounting surface of the package substrate, the mold compound forming the body of a microelectronic device package, the terminals of the package substrate forming terminals of the microelectronic device package.

### TECHNICAL FIELD

This disclosure relates generally to electronic packaging, and more particularly to packaging semiconductor devices and associated passive components in a microelectronic device package to form a system.

### BACKGROUND

The semiconductor industry continually develops packaged devices with more functionality in a single packaged device, which can be referred to as “multi-chip modules” or “system-in-a-package” or “SIP” devices. By providing a functional semiconductor device and including the necessary passive components and semiconductor device dies to form a commonly needed function in a single package, users are freed from the necessity of determining the values and types of various passive components needed with a semiconductor device die to perform these common functions. By integrating these devices into a single microelectronic device package, the system board area needed to implement the function is reduced. Examples include power supplies, power converters, battery chargers, and power controllers. In automotive systems, DC-DC converters that output DC power at various DC voltages from a battery or alternator power source are often needed. A DC-DC converter may include a power semiconductor device die, such as a switching power controller and a power transistor or a power transistor gate driver, along with various passive components such as capacitors, resistors, and inductors to form a complete power converter system.

The passive components used in system-in-package devices can include ceramic capacitors, which can have two terminals. These two terminal passive components can be mounted near the semiconductor device die on a package substrate, and traces on the package substrate can couple the devices together. One example application for an integrated capacitor is a bypass capacitor, which can be coupled between a voltage input terminal on a semiconductor device and a ground terminal. By coupling a capacitor in this manner, high frequency or AC noise that can occur during switching power operations is filtered from the power terminal, which prevents the AC noise from adversely impacting the circuit operation or from entering the output signals of the system.

Ceramic capacitors placed as passive components on package substrate traces create both reliability and performance issues. While the ceramic capacitors are readily available, a reliability issue can arise that relates to the fact the value of the ceramic capacitors can drift over the life of the microelectronic device, particularly when the microelectronic device package is used in automotive or other applications where the device is exposed to a wide range of temperatures, especially high temperatures. As the ceramic capacitors degrade, the value of the components can change, causing erroneous operation or failures in the devices. In addition, when passive components are coupled to the semiconductor devices using conductive traces on a package substrate, a loop inductance forms. This loop inductance requires additional capacitor compensation in the form of relatively high value capacitors, which require more package substrate area in the microelectronic device package.

Thus, there is a continuing need for increasingly reliable and increased integration in providing passive components with semiconductor device dies in a microelectronic device package.

### SUMMARY

In another described example, an apparatus includes: a passive component die mounted to a device side surface of a semiconductor device die, and extending away from the device side surface of the semiconductor device die; the semiconductor device die and the passive component die flip chip mounted to a device mounting surface of a package substrate including a cavity extending into the package substrate from the device mounting surface of the package substrate, the cavity in a position corresponding to the passive component die, the passive component die extending into the cavity of the package substrate, and the package substrate having terminals on a board side surface; and mold compound covering the semiconductor device die, the passive component die, and the device mounting surface of the package substrate, the mold compound forming the body of a microelectronic device package, the terminals of the package substrate forming terminals of the microelectronic device package.

In a further described example, a microelectronic device package includes a semiconductor device die and a semiconductor trench capacitor die mounted to a device side surface of the semiconductor device die using solder bumps, the trench capacitor die extending away from the device side surface of the semiconductor device die. The semiconductor device die and the semiconductor trench capacitor die are flip chip mounted to a device mounting surface of a package substrate, the package substrate having a cavity extending into the package substrate from the device mounting surface of the package substrate, the cavity in a position corresponding to the semiconductor trench capacitor die that extends into the cavity of the package substrate, and the package substrate having terminals on a board side surface. Mold compound covers the semiconductor device die, the semiconductor trench capacitor die and the device mounting surface of the package substrate, the mold compound filling space in the cavity around the trench capacitor semiconductor die, the mold compound forming the body of a microelectronic device package, the terminals of the package substrate forming terminals of the microelectronic device package.

In a further described example, a method includes: mounting a passive component die to a device side surface of a semiconductor device die using conductive post connects that extend from the semiconductor device die and have solder at a distal end; subsequently flip chip mounting the semiconductor device die to a device mounting surface of a package substrate, the package substrate having terminals on a board side surface opposite the device mounting surface, the passive component die extending into a cavity extending into the package substrate from the device mounting surface of the package substrate, the passive component die spaced from the sides and a bottom surface of the cavity; and covering the semiconductor die, the passive component die, and the device mounting surface of the package substrate with mold compound, the mold compound forming the body of a microelectronic device package.

### BRIEF DESCRIPTION OF THE DRAWINGS

FIGS. 1A-1C are cross-sectional drawings of components of an apparatus that is an example microelectronic device package.

FIGS. 2A-2C are perspective views of the components of the apparatus of FIG. 1.

FIGS. 3A and 3B illustrate in two projection views a semiconductor wafer having semiconductor devices formed on it and configured for flip chip mounting, and an individual semiconductor device die for flip chip mounting, respectively.

FIG. 3C illustrates a passive component die for use in an arrangement.

FIG. 4 illustrates in a cross-sectional view an example multilayer package substrate.

FIGS. 5A-5B illustrate, in a series of cross-sectional views, selected steps for a method for forming a multilayer package substrate that is useful with the arrangements.

FIG. 6A illustrates, in a cross-sectional view, an example arrangement with a passive component die mounted to a semiconductor device die in a microelectronic device package. FIGS. 6B-6C illustrate, in two additional cross-sectional views, particular details of an example arrangement. FIG. 6D illustrates, in a top view from a device side surface, a passive component die mounted to the device side surface of a semiconductor device die.

FIGS. 7A-7D illustrate, in a series of cross-sectional views, a method for forming a cavity in a surface of a multilayer package substrate for use in an arrangement.

FIGS. 8A-8B illustrate, in two cutaway views from different points, details of an example arrangement of a semiconductor device die and a passive component die mounted to a multilayer package substrate.

FIG. 9 is a projection view of a thermally enhanced QFN package that is useful with an arrangement.

FIG. 10 illustrates a process flow diagram of an example process for forming an arrangement.

### DETAILED DESCRIPTION

In the drawings, corresponding numerals and symbols generally refer to corresponding parts unless otherwise indicated. The drawings are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor device die” is used herein. A semiconductor device die can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor die can include passive devices such as resistors, inductors, filters, sensors, or active devices such as transistors. The semiconductor device die can be an integrated circuit with hundreds, or thousands of transistors coupled to form a functional circuit, for example a microprocessor or memory device.

The term “passive component die” is used herein. A passive component die is a passive component fabricated as a semiconductor die. For example, a passive component die can be a trench capacitor die (TCAP die). A trench capacitor is formed in a semiconductor manufacturing facility on a wafer by forming a well or tank in a semiconductor substrate as a bottom plate, forming a trench extending into the bottom plate, depositing dielectric material into the trench, and forming conductive material such as doped polysilicon or metal gate material over the dielectric material to form a top plate. Conductors are formed over the semiconductor substrate to form bond pads electrically coupled to the bottom plate and the top plate to complete the passive component. The wafer is singulated into individual dies, which are passive component dies. Other passive components including resistors, coils, inductors, diodes, and sensors can be formed as passive component dies and can be used in the arrangements.

The term “microelectronic device package” is used herein. A microelectronic device package has at least one semiconductor device die electrically coupled to terminals and has a package body that protects and covers the semiconductor die. The microelectronic device package can include additional elements, in example arrangements an integrated passive component die is included. Other passive components such as capacitors, resistors, and inductors or coils can also be included. In some arrangements, multiple semiconductor device dies can be packaged together. For example, a power metal oxide semiconductor (MOS) field effect transistor (FET) semiconductor die, and a logic semiconductor device die (such as a gate driver die, or a power FET controller die) can be packaged together to from a single microelectronic device package. These integrated devices can be referred to as “multichip modules” or “system-in-package” (or “SIP”) devices. In example arrangements, a semiconductor device die is mounted to a package substrate that provides conductive leads; a portion of the conductive leads form the terminals for the packaged device. The semiconductor device die can be flip chip mounted to the package substrate with a device side surface facing the substrate and a backside surface facing away from the package substrate. In flip chip semiconductor device packages, conductive post connects that extend from bond pads on the semiconductor device die and have solder deposited on a distal end couple conductive leads of a package substrate to bond pads on the semiconductor device die. The semiconductor device package can have a package body formed by a thermoset epoxy resin in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions provide the terminals for the semiconductor device package.

The term “package substrate” is used herein. A package substrate is a substrate arranged to receive a semiconductor die and to support the semiconductor die in a completed semiconductor device package. Package substrates useful with the arrangements include multilayer package substrates. Multilayer package substrates have trace level conductors spaced by dielectric material in layers, and vertical connection layers that extend through the dielectric material between trace level conductors to form routing networks. Alternative package substrates that can be used include conductive leadframes, which can be formed from copper, aluminum, stainless steel, steel, and alloys such as Alloy 42 and copper alloys. The leadframes can include a die pad with a die side surface for mounting a semiconductor die, and conductive leads arranged near and spaced from the die pad for coupling to bond pads on the semiconductor die. Semiconductor device dies can be flip chip mounted to the leadframes using conductive post connects to couple the bond pads of the semiconductor device die to conductive lands on the leadframe. These packages can be referred to as “flip chip on leadframe” or “FCOL” packages. In a process for mounting the semiconductor device dies, the leadframes can be provided in strips or arrays. The conductive leadframes can be provided as a panel with strips or arrays of unit device portions in rows and columns. Semiconductor dies can be placed on respective unit device portions within the strips or arrays. A semiconductor die can be placed on a die pad for each packaged device and die attach or die adhesive can be used to mount the semiconductor dies to the leadframe die pads.

The term “build-up package substrate” is used herein. A build-up package substrate is a multilayer package substrate that has multiple trace level conductor layers, and which has vertical connection layers extending through dielectric material between the trace level conductor layers. In an example arrangement, a build-up package substrate is formed in an additive process by plating a patterned conductor level and then covering the conductor with a layer of film dielectric material. The film dielectric material can be applied at an elevated temperature to soften the material, and a vacuum can be used to cause the film dielectric material to conform to the conductors underneath. The film dielectric material can then be thermally cured to harden the dielectric material. Multiple layers of the film dielectric material can be applied. Grinding can be performed on the dielectric material to expose portions of the layer of conductors. Additional plating layers can be formed to add additional levels of conductors, some of which are coupled to the prior trace level conductor layers by vertical connection layers, and additional film dielectric material can be deposited at each level and can cover the conductors. By using an additive or build up manufacturing approach, and by performing multiple plating steps, molding steps, and grinding steps, a build-up package substrate can be formed with an arbitrary number of layers. In an example arrangement, copper conductors are formed by plating, and a thermoplastic material can be used as the dielectric material. In a particular example, the dielectric film can be an epoxy-based build-up film commercially available as “Ajinomoto Build-up Film,” from Ajinomoto Co., Inc., of Tokyo, Japan.

In packaging microelectronic and semiconductor devices, mold compound may be used to partially cover a package substrate, to cover components, to cover a semiconductor die, and to cover the electrical connections from the semiconductor die to the package substrate. This molding process can be referred to as an “encapsulation” process, although some portions of the package substrates are not covered in the mold compound during encapsulation, for example terminals and leads are exposed from the mold compound. Encapsulation is often a compressive molding process, where thermoset mold compound such as resin epoxy can be used. A room temperature solid or powder mold compound can be heated to a liquid state and then molding can be performed by pressing the liquid mold compound into a mold through runners or channels. Transfer molding can be used. Compression molding can be used, where the units to be covered with mold compound are pressed into a two-part mold with mold compound to force the mold compound to fill the mold. Unit molds shaped to surround an individual device may be used, or block molding may be used, to form multiple packages simultaneously for several devices from mold compound. The devices to be molded can be provided in an array or matrix of several, hundreds or even thousands of devices in rows and columns that are then molded together. When mold compound is formed over the components mounted to a device mounting surface of a package substrate, it may be referred to as an “overmolding” process.

After the molding, the individual packaged devices are cut from each other in a sawing operation by cutting through the mold compound and package substrate in saw streets formed between the devices. Portions of the package substrate leads are exposed from the mold compound package to form terminals for the microelectronic device packages.

The term “scribe lane” is used herein. A scribe lane is a portion of semiconductor wafer between semiconductor dies. Sometimes in related literature the term “scribe street” or “scribe line” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser, or other cutting tool to pass between the molded electronic devices to separate the devices from one another. This process is another form of singulation. When the molded electronic devices are provided in a strip with one device adjacent to another device along the strip, the saw streets are parallel and normal to the length of the strip. When the molded electronic devices are provided in an array of devices in rows and columns, the saw streets include two groups of parallel saw streets, the two groups are normal to each other, and the saw will traverse the molded electronic devices in two different directions to cut apart the packaged electronic devices from one another in the array.

The term “quad flat no-lead” (QFN) is used herein for a type of electronic device package. A QFN package has conductive leads that are coextensive with the sides of a molded package body, and the leads are on four sides. Alternative flat no-lead packages may have leads on two sides or only on one side. These can be referred to as small outline no-lead or SON packages. No-lead packaged electronic devices can be surface mounted to a board. Leaded packages can be used with the arrangements where the leads extend away from the package body and are shaped to form a portion for soldering to a board. A dual in-line package (DIP) can be used with the arrangements. A small outline package (SOP) can be used with the arrangements. Small outline no-lead (SON) packages can be used, and a small outline transistor (SOT) package is a leaded package that can be used with the arrangements.

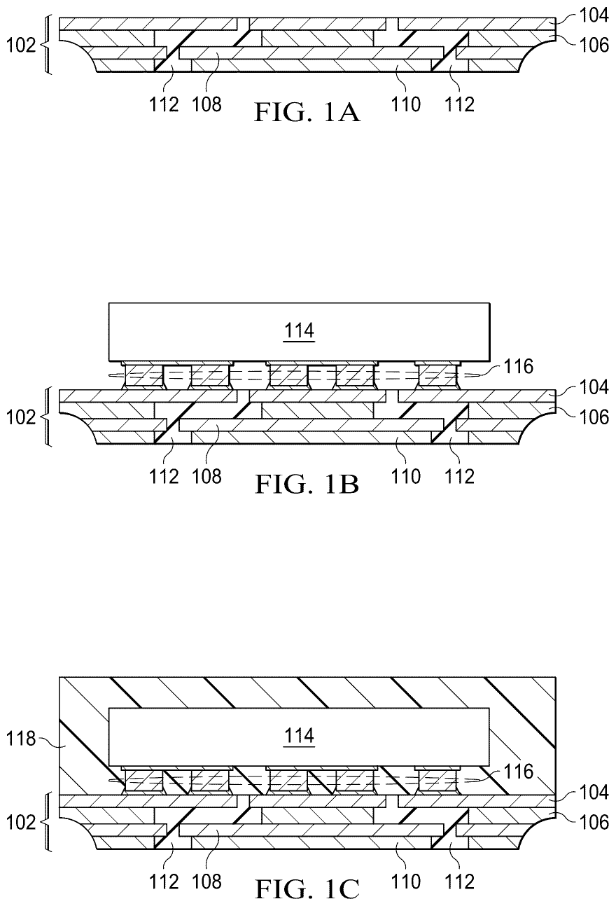

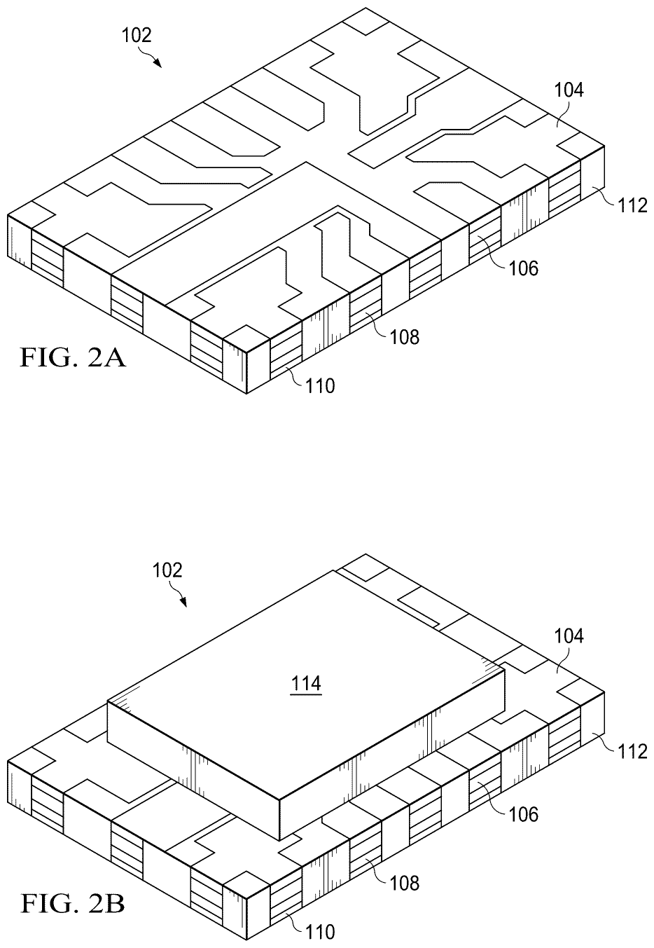

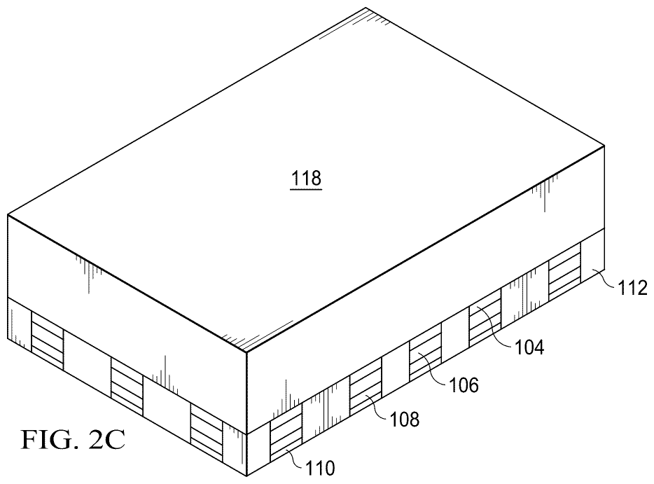

FIGS. 1A-1C are cross-sectional drawings illustrating a package substrate, a semiconductor device die flip chip mounted to the package substrate, and a microelectronic device package formed by covering the semiconductor device and a portion of the package substrate with mold compound. FIGS. 2A-C are perspective diagrams of the components illustrated in FIGS. 1A-1C.

In FIG. 1A, an example multilayer package substrate 102 includes four layers: first layer 104, second layer 106, third layer 108, and fourth layer 110. Each of these layers can have a patterned conductive layer including copper, silver, titanium, gold, or other conductive materials, including alloys of these conductive materials. In this example multilayer package substrate 102, layer 110 is on the board side of the package substrate 102, and portions of layer 110 are shaped to form terminals for a microelectronic device package. Layer 104 is on the device mounting surface of the package substrate 102, and portions of this layer are arranged to form conductive lands for receiving a flip chip mounted semiconductor device die. The portion of each conductive layer 104, 106, 108, 110 that does not include conductive material is filled with dielectric material such as dielectric 112. The dielectric material 112 of the multilayer package substrate 102 can be a thermoplastic or a thermoset material.

In a process useful with the arrangements, the multilayer package substrate 102 can be a build-up package substrate. Build-up package substrates can be formed by using sputter deposition to deposit a seed layer on a carrier or film, masking the seed layer, plating a conductor layer on the seed layer, removing unwanted portions of the seed layer, and then using an epoxy film to form the dielectric material, this process is performed repeatedly in laminated layers. An example film used in forming build-up substrates is Ajinomoto Build-Up Film (ABF). By using an additive process to form the build-up substrate in layers, arbitrary conductor shapes can be formed including rails or other rectangular shapes as vertical connection layers between the trace level conductors. By forming conductor shapes vertically using the ABF process, the conductors can be stacked to form columns, blocks, or rails of various thicknesses to form low resistance paths between devices on the device side surface of the package substrate and terminals on a board side surface. An alternative example thermoplastic material is ABS (Acrylonitrile Butadiene Styrene). Other alternative dielectric materials include thermoplastics such as ASA (Acrylonitrile Styrene Acrylate), thermoset mold compound including epoxy resin, epoxies, resins, or plastics. A perspective view of multilayer package substrate 102 is shown in FIG. 2A.

FIG. 1B shows an example semiconductor device die 114 that is flip chip mounted on multilayer package substrate 102. Semiconductor device die 114 includes conductive post connects 116. Conductive post connects 116 are formed on bond pads (not shown in this figure) on the surface of semiconductor device die 114. A solder bump (not shown in this figure) can be formed on top of each of the distal ends of the conductive post connects. The semiconductor device die is then flipped over so that the device side surface faces the device mounting surface of the package substrate, and the die positioned so that the solder bumps contact pads in first layer 104. Compression, heat, or vibration is used to form a conductive connection from first layer 104 to conductive connection posts 116 via the solder bumps. A perspective view of semiconductor device die 114 mounted on multilayer package substrate 102 is shown in FIG. 2B.

FIG. 1C is a cross-sectional view of die 114 mounted on multilayer package substrate 102 after an encapsulation by a mold compound 118. Mold compound is an example encapsulant, and is a thermoset epoxy resin, other thermoplastics, resins, and epoxies can be used. The completed package shown in the example of FIG. 1C and FIG. 2C is a quad flat no-lead (QFN) package. QFN packages are one type of microelectronic device package that is useful with the arrangements. Other package types including leaded and other no lead packages can be used. QFN packages are particularly attractive as the system board area needed to mount a QFN package is reduced compared to similar leaded packages. In a QFN package, the terminals are within the area of the package body, reducing the size of the board land pattern needed for mounting the devices.

FIGS. 1A-1C and 2A-2C illustrate certain details of flip chip semiconductor device die mounts using multilayer package substrates in microelectronic device packages. Not shown in FIGS. 1A-1C and 2A-2C are additional components such as capacitors, resistors, or inductors that can be mounted with the semiconductor dies to form system-in-package devices.

In example arrangements, a semiconductor device die combined with a passive component die, for example a capacitor, is mounted to a device mounting surface of a package substrate. In forming the arrangements, the semiconductor device dies, and the passive component dies, can be formed independently of the package substrate, so that methods for forming the semiconductor device die, the passive component die, and the package substrate can be performed at various times, and at various locations. The components can be assembled to complete the arrangements. In an example arrangement, prior to flip chip mounting the semiconductor device die to the package substrate, a passive component die, which is a trench capacitor die (“TCAP”) is first mounted to the device side surface of the semiconductor device die using solder bumps, as is further described below.

The passive component die can be a discrete trench capacitor, and more particularly, can be a silicon trench capacitor. Trench capacitors or TCAPs can be formed in a semiconductor manufacturing facility using processes also used to form other semiconductor devices. The passive component dies can be formed as a wafer of individual dies, and then singulated to form individual passive component dies. In example arrangements, the passive component dies can be a trench capacitor (TCAP) component die. Semiconductor trench capacitors are used in example arrangements, in additional alternative other passive component die types can be used.

After the passive component die is mounted to a semiconductor device die using solder bumps, the passive component die will extend away from the device side surface of the semiconductor device die. When the combined devices are subsequently flip chip mounted to a package substrate in the arrangements, the package substrate includes a cavity formed into the device mounting surface of the package substrate at a position corresponding to the position of the passive component die when mounted. The passive component die extends into the cavity, allowing the combined semiconductor device die and the passive component die to be flip chip mounted. Because the passive component die is located beneath the semiconductor device die, no additional package substrate area is required for the passive component die, in sharp contrast to the use of discrete components mounted on a package substrate such as ceramic capacitor components used in prior approaches. Further, in an example where the passive component die is a TCAP, because the TCAP is directly mounted to the semiconductor device die without conductive traces, the loop inductance that results from prior approaches is reduced or minimized. This advantage of the arrangements further results in enabling the needed capacitance value of the TCAP to be reduced (compared to the ceramic capacitors used in prior approaches), making the size of the TCAP passive component die that is needed compatible with the semiconductor device die area, so that the TCAP passive component die is of less area than the semiconductor device die, and in example arrangements, is covered by the semiconductor device die. The TCAP passive component die can also have a thickness less than the thickness of the package substrate, as is further described below, so that the passive component die fits within the thickness of the package substrate.

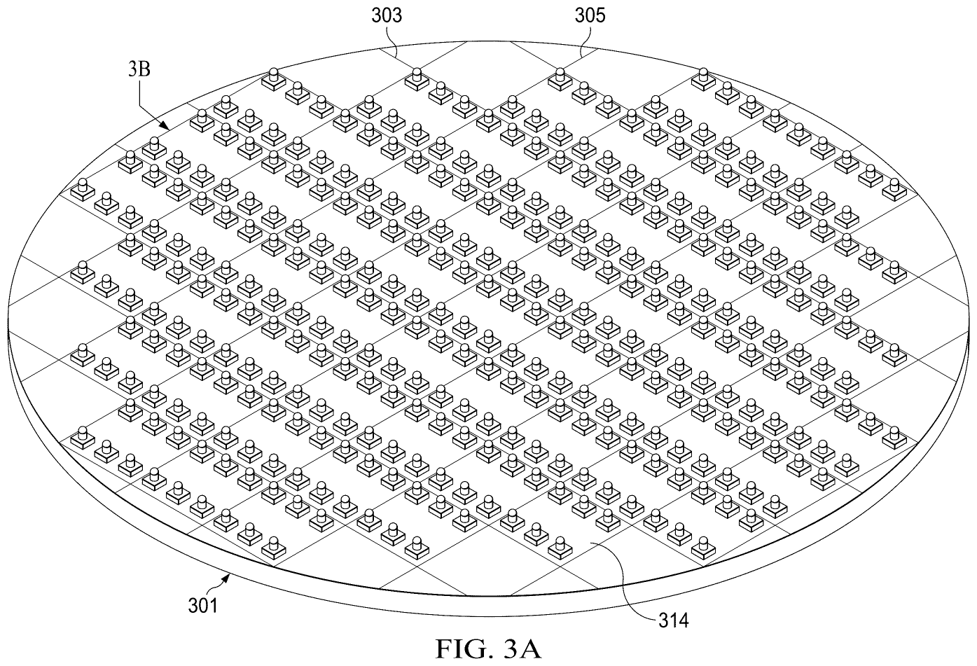

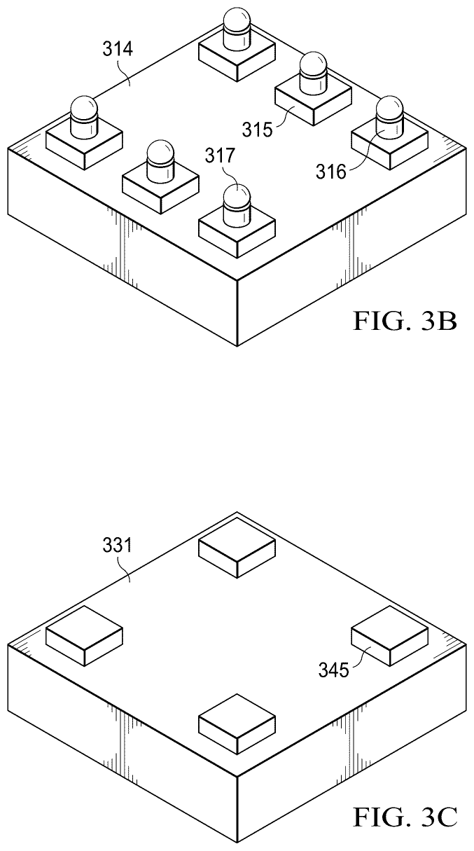

FIGS. 3A and 3B illustrate in two projection views a semiconductor wafer having semiconductor devices formed on it and configured for flip chip mounting, and an individual semiconductor device die configured for flip chip mounting, respectively. In the arrangements, a semiconductor device die ready for mounting can be formed using wafer bumping. In wafer bumping, after the semiconductor devices in the semiconductor substrate are completed as individual dies in a semiconductor manufacturing process, conductive post connects extending from bond pads on the semiconductor dies can be formed by a plating process. Solder can be deposited or formed on the distal ends of the conductive post connects. Various conductor materials can be used such as copper, gold, and aluminum. Copper is often used. When the conductive post connects are of copper, the term “copper pillar” is often used. When solder is applied to the distal end and then shaped as a bump shape in a thermal reflow process, the conductive post connects can be described as “copper pillar bumps.” Solder bumps can also be used.

In FIG. 3A, an example semiconductor wafer 301 is shown with an array of semiconductor device dies 314 formed in rows and columns on a surface. The semiconductor device dies 314 can be formed using processes in a semiconductor manufacturing facility, including ion implantation, doping, anneals, oxidation, dielectric and metal deposition, photolithography, pattern, etch, photoresist stripping, chemical mechanical polishing (CMP), electroplating, and other processes for making semiconductor devices. Scribe lanes 303 and 305, which are perpendicular to one another, and which run in parallel groups across the semiconductor wafer 301, separate the rows and columns of the completed semiconductor device dies 314, and provide defined areas for dicing the wafer 301 in a singulation operation, to separate the semiconductor device dies 314 from one another.

FIG. 3B illustrates a single semiconductor device die 314, with bond pads 315, which are conductive pads that are electrically coupled to devices (not shown) including transistors and circuitry formed in the semiconductor device die 314. Conductive post connects 316 are shown extending away from a proximate end mounted on the bond pads 315 on the surface of semiconductor device die 314 to a distal end, and solder bumps 317 are formed on the distal ends of the conductive post connects 315. The conductive post connects 316 can be formed by electroless plating or electroplating. In an example, the conductive post connects 316 are copper pillar bumps. Copper pillar bumps can be formed by sputtering a seed layer over the surface of the semiconductor wafer 301, forming a photoresist layer over the seed layer, using photolithography to expose the bond pads 315 in openings in the layer of photoresist, plating the copper conductive connection posts 316 on the bond pads, and plating a lead solder or a lead-free solder such as an tin, silver (SnAg) or tin, silver, copper (SnAgCu) or SAC solder to form solder bumps 317 on the distal ends of the copper post connects 316. In alternative approach, solder bumps or particles may be dropped onto the distal ends of the copper post connects and then reflowed in a thermal process to form solder bumps. Other conductive materials can be used for the conductive post connects in electroplating or electroless plating operation, including gold, silver, nickel, palladium, or tin, for example. Not shown for clarity of illustration are under bump metallization (UBM) portions which can be formed over the bond pads to improve plating and adhesion between the conductive connection posts 316 and the bond pads 315. After the plating operations, the photoresist is then stripped, and the excess seed layer is etched from the surface of the wafer. The semiconductor device dies 314 are then separated by dicing, or are singulated, using the scribe lanes 303, 305 (see FIG. 3A).

FIG. 3C illustrates, in another projection view, an example passive component die 331 that can be formed in another semiconductor fabrication process. In a particular example arrangement, the passive component die 331 can be a trench capacitor (TCAP). However, in additional arrangements the passive component die 331 can be a resistor, an inductor, a coil, a diode, or a sensor. The passive component die 331 will be mounted to a semiconductor device die (see 314 in FIG. 3B, for example) that has conductive post connects formed on a device side surface. Accordingly, the passive component die 331 has bond pads 345 on a device side surface of the passive component doe that are arranged to be mounted to the semiconductor device die. The passive component die 331 is a semiconductor die and can be formed in a semiconductor manufacturing process on a wafer scale, similar to the semiconductor device dies 314 on wafer 301.

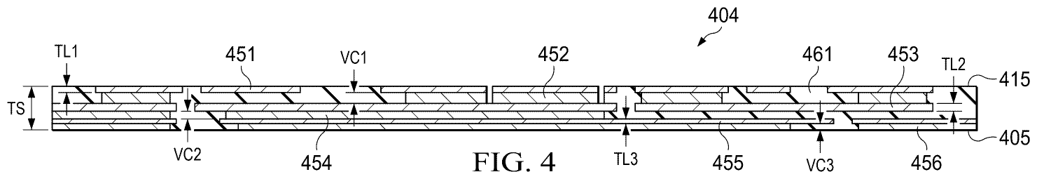

FIG. 4 illustrates in a cross-sectional view a multilayer package substrate 404 that can be used with the arrangements. In FIG. 4, the multilayer package substrate 404 has a device mounting surface 415 and a board side surface 405. Three trace level conductor layers 451, 453, 455 are formed spaced from one another by dielectric material 461, the trace level conductor layers are patterned for making horizontal connections, and three vertical connection layers 452, 454, 456 form electrical connections between the three trace level conductor layers 451, 453, 455 and extend through the dielectric material 461 that is disposed over and between the trace level conductor layers. The dielectric material 461 can be a build-up dielectric film such as ABF, another thermoplastic material such as ABS, or ASA, or can be a thermoset material, such as epoxy resin mold compound.

The package substrate can have various thicknesses. In one example the multilayer package substrate 404 has a substrate thickness labeled “TS” of about 200 μm. The various trace level conductor layers and dielectric layers between the trace level conductor layers, including the vertical connection layers, can have varying thickness as well. These thicknesses taken together can add up in total to the substrate thickness TS. In a particular example of a multilayer package substrate useful with the arrangements, the first trace level conductor layer, 451, near the device mounting surface 415 of the multilayer package substrate, can have a trace level conductor layer thickness TL1 of 15 μm. The first vertical connection layer, 452, can have a thickness VC1 of 25 μm. The second trace level conductor layer, 453, sometimes coupled to the first trace level conductor layer 451 by the first vertical connection layer 452, can have a thickness labeled TL2 of 60 μm. The second vertical connection layer, 454, can have a thickness labeled VC2 of 65 μm. The third trace level conductor layer, 455, can have a thickness labeled TL3 of 15 μm, and the third vertical connection layer, 456, can have a thickness labeled VC3 of 25 μm. Additional layers, such as conductive lands on the device side surface 415, or terminals on the board side surface 405, may be formed by plating (not shown in FIG. 4). A continuous vertical connection between the device side surface 415 and the board side surface 405 can be formed by patterning a stack of the trace level conductor layers and the corresponding vertical connection layers to form a continuous conductive path extending vertically through the dielectric material 461.

Note that in this description, the vertical connection layers 452, 454, and 456 are not described as “vias.” This is intentionally done in this description to distinguish the vertical connection layers of the build-up multilayer package substrate of the arrangements from the via connections of PCBs or other substrates, which are filled holes. The vertical connections of the arrangements can be formed using additive manufacturing, while in contrast, the vias in PCBs are usually formed by removing material, for example by via holes that are drilled into the substrate. These via holes between conductor layers then must be plated and filled with a conductor, which requires additional plating steps after the drilling steps. These additional process steps are precise manufacturing processes that add costs and require additional manufacturing tools and capabilities.

In contrast to conventional vias, the vertical connection layers used in the build-up process to form multilayer package substrates of the arrangements are formed in the same plating processes as those used in forming the trace level conductor layers, simplifying manufacture, and reducing costs. In addition, the vertical connection layers in the arrangements can be arbitrary shapes, such as rails, columns, or posts, and the rails can be formed in continuous patterns to form electric shields, tubs, or tanks, and can be coupled to grounds or other potentials, isolating regions of the multilayer package substrate from one another. Noise reduction and the ability to create electrically isolated portions of the multilayer package substrate can be enhanced by use of the vertical connections to form tanks, shields, and tubs. Thermal performance of the microelectronic device packages of example arrangements can be improved by use of the trace level conductor layers and vertical connection layers to form thermally conductive columns, sinks or rails that can be coupled to thermal paths on a system board to increase thermal dissipation from the semiconductor devices mounted on the multilayer package substrate.

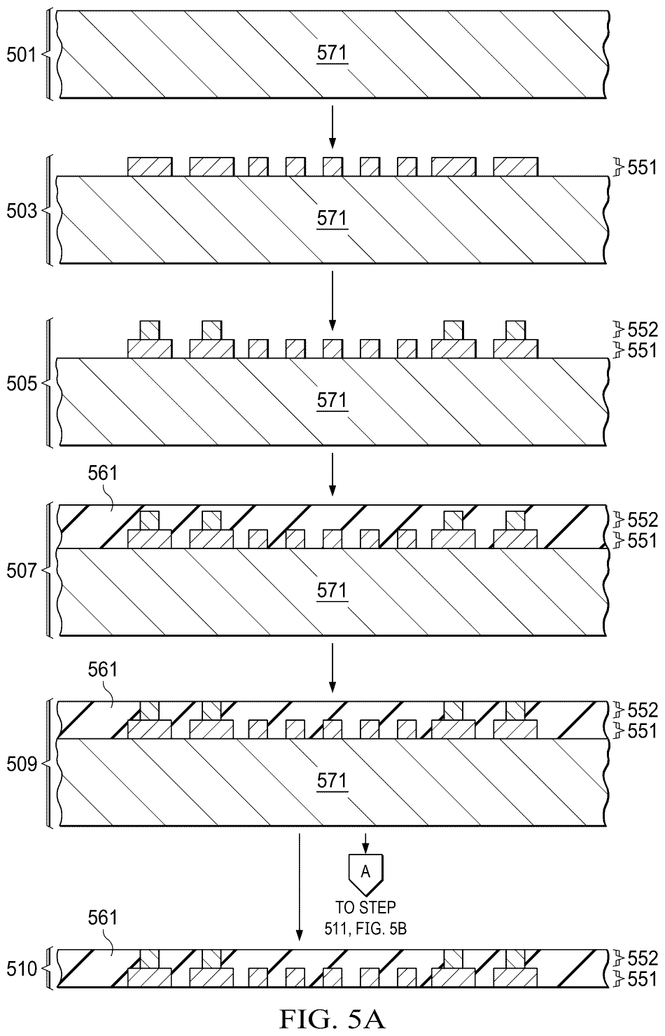

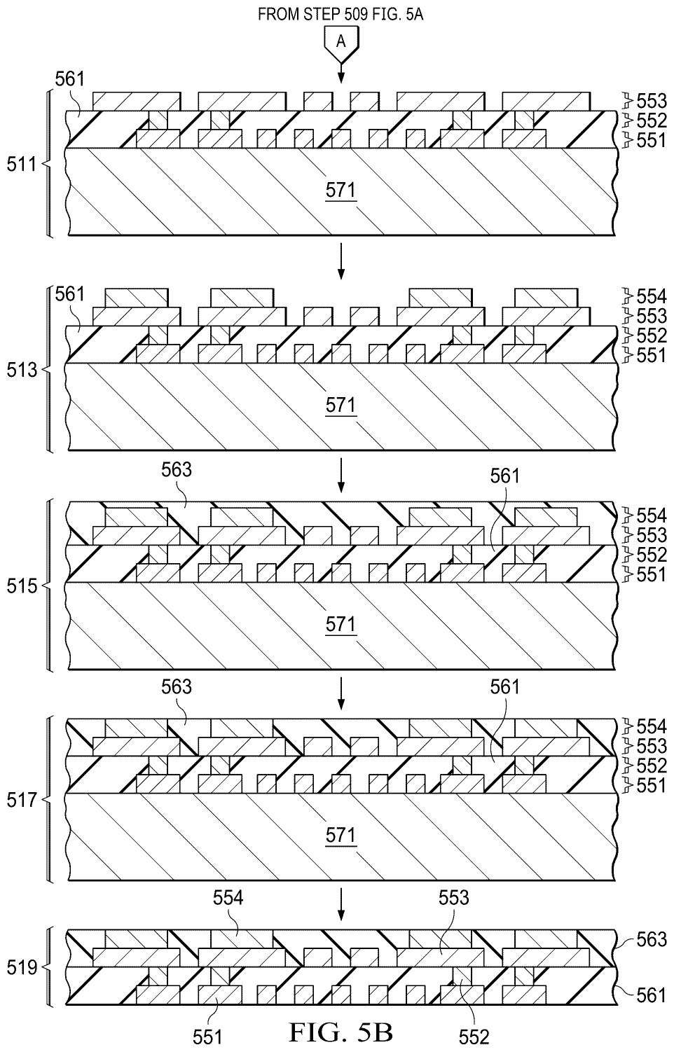

FIGS. 5A-5B (collectively “FIG. 5”) illustrate, in a series of cross-sectional views, selected steps for a method for forming a build-up multilayer package substrate that is useful with the arrangements. In FIG. 5A, at step 501, a metal carrier 571 is ready for a plating process. The metal carrier 571 can be stainless steel, steel, aluminum, or another metal that will support the multilayer package substrate layers during plating and molding steps, the multilayer package substrate is then removed, and the metal carrier is cleaned for additional manufacturing processes.

At step 503, a first trace level conductor layer 551 is formed by plating. In an example process, a seed layer is deposited over the surface of metal carrier 571, by sputtering, chemical vapor deposition (CVD) or other deposition step. A photoresist layer is deposited over the seed layer, exposed, developed, and cured to form a pattern to be plated. Electroless or electroplating is performed using the exposed portions of the seed layer to start the plating, forming a pattern according to patterns in the photoresist layer.

At step 505, the plating process continues. A second photoresist layer is deposited, exposed, and developed to pattern the first vertical connection layer 552. In this example process, the process is simplified by leaving the first photoresist layer in place, the second photoresist layer is used without an intervening strip and clean step. The first trace level conductor layer 551 can be used as a seed layer for the second plating operation, to further simplify processing. However, in an alternative process, a seed layer can be deposited for each conductive layer, and plating can be performed using each successive seed layer.

At step 507, a dielectric layer is formed. The first trace level conductor layer 551 and the first vertical connection layer 552 are covered in a dielectric material. In an example using ABF, the dielectric is provided as a film. The film is warmed to make it conformal, and stretched over layers 551, 552. A vacuum process can be used to cause the film to conform to the shapes of the conductors without voids. A curing process then hardens the film into a solid dielectric material. Alternatives include a thermoplastic material such as ABS; in alternative further examples ASA can be used, or a thermoset epoxy resin mold compound can be used, or resins, epoxies, or plastics can be used. In an example compressive molding operation, a mold compound can be heated to a liquid state, forced under pressure through runners into a mold to cover the first trace level conductor layer 551 and the first vertical connection layer 552, and subsequently cured to form solid mold compound 561.

At step 509, a grinding operation is performed on the surface of the dielectric material 561 and exposes a surface of the first vertical connection layer 552 and provides conductive surfaces for mounting devices, or for use in additional plating operations. If the multilayer package substrate is complete, the method ends at step 510, where a de-carrier operation removes the metal carrier 571 from the mold compound 561, leaving the first trace level conductor layer 551 and the first vertical connection layer 552 in a mold compound 561, providing a package substrate.

In examples where additional trace level conductor layers and additional vertical connection layers are needed, the method continues, leaving step 509 and transitioning to step 511 in FIG. 5B.

At step 511, a second trace level conductor layer 553 is formed by plating using the same processes as described above with respect to step 505. A seed layer for the plating operation is deposited and a photoresist layer is deposited and patterned, and the plating operation forms the second trace level conductor layer 553 over dielectric 561, with portions of the second trace level conductor layer 553 electrically connected to the first vertical connection layer 552.

At step 513, a second vertical connection layer 554 is formed using an additional plating step on the second trace level conductor layer 553. The second vertical connection layer 554 can be plated using the second trace level conductor layer 553 as a seed layer, and without the need for removing the preceding photoresist layer, simplifying the process. Alternatively, each successive layer can be formed using a seed layer and photolithography to pattern the plated layers.

At step 515, a second dielectric deposition is performed to cover the second trace level conductor layer 553 and the second vertical connection layer 554 in a layer of dielectric material 563. The dielectric film deposition, vacuum, and cure steps are again performed as described above. The multilayer package substrate at this stage has a first trace level conductor layer 551, a first vertical connection layer 552, a second trace level conductor layer 553, and a second vertical connection layer 554, portions of the layers are electrically connected to form vertical paths through the layers of dielectric material 561 and 563.

At step 517, the dielectric material 563 is mechanically ground in a grinding process or chemically etched to expose a surface of the second vertical connection layer 554.

At step 519 the example method ends by removing the metal carrier 571, leaving a build-up package substrate including the trace level conductor layers 551, 552, 553 and 554 in dielectric material 561, 563. The steps of FIGS. 5A-5B can be repeated to form multilayer package substrates for use with the arrangements having more layers, by performing plating of a trace level conductor layer, plating of a vertical connection layer, applying dielectric firm or molding a dielectric layer, and grinding, repeatedly.

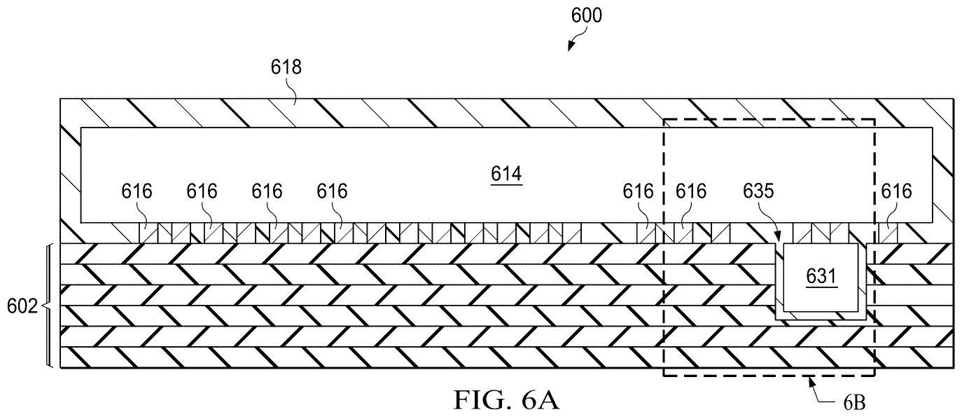

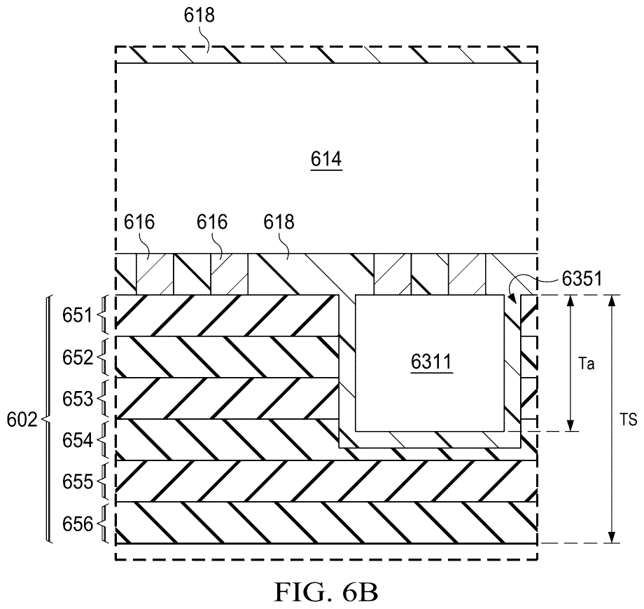

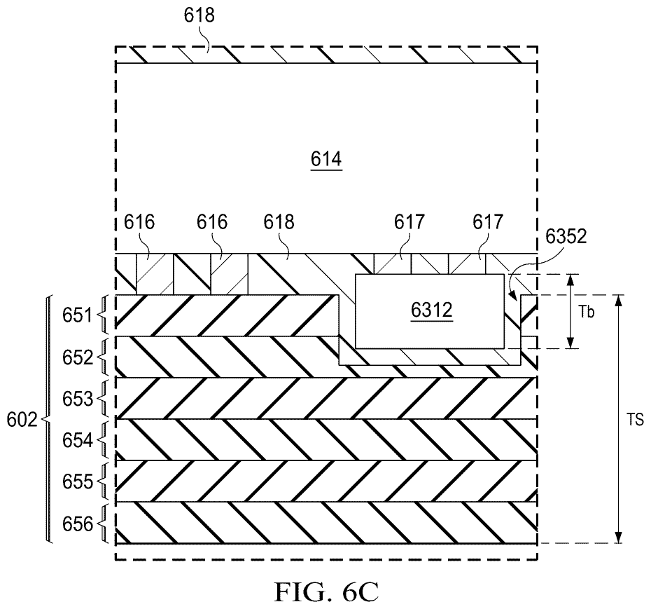

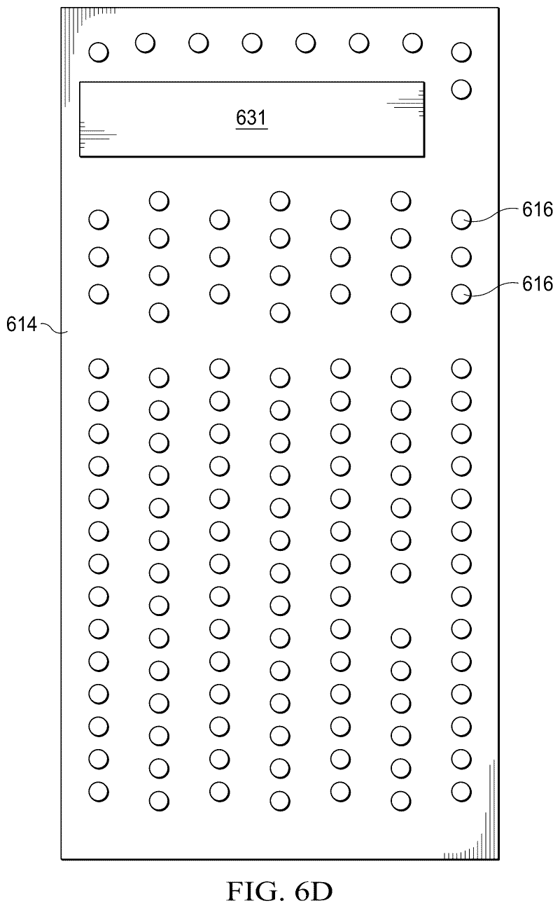

FIG. 6 is a cross-sectional view of an example arrangement for a microelectronic device package 600 including a passive component die, a semiconductor device die, and a multilayer package substrate. In FIG. 6, semiconductor device die 614 is shown with a passive component die 631 that is solder bump mounted to a device side surface of the semiconductor device die 614. The combined components of semiconductor device die 614 and the passive component die 631 are flip chip mounted to the device mounting surface of the multilayer package substrate 602, which can be a build-up multilayer package substrate such as 404 shown in FIG. 4, for example. Other package substrates can be used, including leadframes, partially etched leadframes, pre-molded leadframes, or molded interconnect substrates. Conductive post connects 616, which can be in an example process copper pillar bumps), are used to connect the semiconductor device die 614 to the multilayer package substrate 602. A cavity 635 extends into the device mounting surface of the multilayer package substrate 602 and has vertical sides and a horizontal bottom (as the elements are oriented in FIG. 6A, a typical orientation). The sides and bottom of the cavity 635 are spaced from the outside surfaces of the passive component die 631, which is a cube shape, with vertical sides orthogonal to a bottom surface, and a device side surface opposite the bottom surface that is connected to the semiconductor device die 614 by conductive post connects and solder bumps, and the passive component die 631 extends into the cavity 635. The components are arranged so that the bottom surface of the passive component 631 is placed to be proximate to the bottom of the cavity 635 when the semiconductor device die 614 is flip chip mounted to the package substrate 602. Mold compound 618 covers the semiconductor device die 614, and surrounds the passive component die 631. In a particular example arrangement, the passive component die 631 can be a trench capacitor (TCAP). In additional example arrangements, the passive component die 631 can be a resistor, an inductor, a coil, a diode, or a sensor.

The cavity 635 in the multilayer package substrate 602 enables mounting of the passive component die 631 beneath and in the same package substrate area as semiconductor device die 614. This is in contrast to discrete passive components, for example ceramic capacitors, used in prior approaches for system-in-package devices.

In a particular application, the passive component die 631 is a trench capacitor that is coupled as a bypass capacitor and is connected to a power terminal and a ground terminal of the semiconductor device die 614. In operation, high frequency noise that might arise on the power terminal of the semiconductor device die is filtered and passed to ground by the trench capacitor, and because no board traces are used to couple the trench capacitor to the semiconductor device die 614, loop inductance that arises in prior approach packaged devices when using ceramic capacitors coupled by metal traces is minimized or eliminated. Eliminating this loop inductance enables a lower value capacitance TCAP to be used as a bypass capacitor in the arrangements. In one particular example, the passive component 631 can be a trench capacitor of 10-20 nanofarads or 0.01-0.02 microfarads. In a similar circuit design in a prior approach using a ceramic capacitor mounted on a package substrate using metal traces, a value of 0.15 microfarads was needed. The smaller value for the trench capacitor is possible because the loop inductance is advantageously minimized or even eliminated from the circuit by use of the arrangements. Use of a smaller value trench capacitor value also allows the passive component die, the trench capacitor, to be sized to fit in the cavity 635, and completely beneath the semiconductor device die 614, and still provide the necessary functionality in the microelectronic device package 600.

FIGS. 6B-6C illustrate, in additional cross-sectional views, details of example arrangements. The cross-sectional views of FIGS. 6B-6C illustrate the use of passive component dies of different thicknesses with multilayer package substrates.

In FIG. 6B, a portion of an example arrangement is shown that is similar to the example of FIG. 6A. Semiconductor device die 614 is shown with a passive component die 6311 (which is similar to the passive component die 631) in FIG. 6A, and can be, for example, a trench capacitor. In this example, the passive component 6311 has a semiconductor substrate thickness of about 80 microns, and the bump height can be about 65 microns. There is a space between the device side surface of the semiconductor die and the device mounting surface of the package substrate so that some of this combined thickness (80 microns+65 microns=145 microns) is positioned in that space. The passive component die 6311 extends into a cavity 6351 that has a thickness labeled “Ta” in FIG. 6B. In a particular example, the thickness Ta is about 130 microns extending into the package substrate, with a package substrate thickness of about 200 microns. The cavity 6351, which is similar to the cavity of 635 in FIG. 6A, extends through the trace level conductor layer 651, the vertical connection level 652, the trace level conductor layer 653, and the vertical connection level 654. In the example of FIG. 6B the cavity 6351 extends deep enough into the package substrate 602 that most of the trace level conductors and vertical connection levels are not available for routing beneath the cavity 6351.

In FIG. 6C, an example is illustrated using a thinner passive component die 6312 (thinner than 6311 in FIG. 6B). The remaining elements are the same as those shown in FIG. 6B. The thinner passive component 6312 retains more of the trace level conductor layers and vertical connection layers beneath the cavity 6352, allowing for more routing freedom in the vicinity of the cavity. This arrangement allows for greater integration of the components in the microelectronic device package when compared to the arrangement of FIG. 6B. In a particular example, the thickness Tb is about 115 microns. The thickness of the passive component die can be made less by thinning of the passive component wafer during manufacture. In addition, the example shown in FIG. 6C also has lower heights for the conductive post connects 617 used to mount the passive component 6312, for example about 35 microns, compared to the bump height of about 65 microns for the other conductive post connects 616 on the semiconductor device die 614. When the passive component die 6312 is mounted using a lower bump height, a portion of the passive component die lies in the space between the semiconductor device die and the mounting surface of the package substrate, and thus does not extend into the cavity as far as in an example when the solder bump heights are all the same.

FIG. 6D illustrates, in a top view, the device side surface of an example semiconductor device die 614 with a passive component 631 mounted to it, the passive component 631 can be a trench capacitor passive component die. The passive component die is positioned so, from a plan view, it lies within the area of the semiconductor device die 614. When the combined elements of the semiconductor device die 614 and the passive component die 631 are then flip chip-mounted to the package substrate (see, for example, the cross-sectional views of FIGS. 6A-6C, described above), the passive component die is positioned extending into the cavity in the package substrate, and use of the passive component die 631 does not require any area on the surface of the package substrate, increasing integration without the need for additional surface area.

In an approach to add a passive component die 631 to a semiconductor device die 614 that already has an existing pattern of conductive post connects on the device side surface, a depopulation process is used. Conductive post connects, such as copper pillar bumps, which are already positioned in the area where the passive component die is to be mounted, are depopulated. Additional conductive post connects configured to mount the passive component die 631 are then placed on bond pads of the semiconductor device die, and the passive component 631 can be mounted on the additional conductive post connects. Because the passive component die has fewer bonds than the pattern on the semiconductor device die provided, there will be fewer additional conductive post connects for the passive device die, and the additional conductive post connects can have greater spacing distance between them than the depopulated conductive post connects that are being replaced.

In an alternative approach, the semiconductor device die has bond pads specifically arranged to receive the passive component die 631, and the conductive post connects are placed accordingly during production of the semiconductor device die, in that case no depopulation is needed. In some examples, a first set of conductive post connects, such as copper pillar bumps, that are used to mount the passive component die have a lower thickness than a second set of conductive post connects used to flip chip mount the semiconductor device die to the package substrate, (see, for example, conductive post connects 617 and thicker conductive post connects 616 in FIG. 6C).

In different examples, the passive component die 631 can be thinned in a wafer thinning process during wafer manufacture, to provide dies of different thicknesses. As the passive component dies get thinner, the depth of the cavity 635 in the package substrate 602 can be made less, and the number of routing layers available beneath the cavity increases, which further increases flexibility in routing the conductors in the package substrate. Examples include thicknesses of the passive component die of 100 microns, 80 microns, and 60 microns, in these examples the passive component die is a silicon trench capacitor die. In addition, alternative arrangements can include different thicknesses for the conductive post connects, such as copper pillar bumps, which are used to mount the passive component die to the semiconductor device die. In examples, the pillar bumps had thicknesses extending from the device side surface of the semiconductor device die of 65 microns, 35 microns, or 20 microns. In addition, in some examples the pillar bumps used to mount the passive component die have less thickness than the remaining pillar bumps used to flip chip mount the semiconductor device die. This reduced thickness allows the passive component to extend a shorter distance into the cavity in the package substrate, again a shallower cavity allows more layers in the multilayer package substrate to be used for routing.

In FIG. 6D, the semiconductor device die 614 is arranged for flip chip mounting and the device side surface visible in FIG. 6D includes the conductive post connects 616, which are coupled to bond pads (not shown) of the semiconductor device die 614. In an assembly method useful with the arrangements, a passive component die 631 is mounted to the device side surface of the semiconductor device die 614 prior to the flip chip mounting of the semiconductor device die 614. The passive component die 631 is shown mounted to the semiconductor device die in FIG. 6D. In one approach that is useful with the arrangements, the passive component die 631 for a plurality of semiconductor device dies 614 on a bumped wafer (see, for example, wafer 301 in FIG. 3A, described above) may be mounted before the semiconductor wafer is singulated. In an alternative approach, individual semiconductor device dies 614 can be placed on a support or carrier, and the passive component die 631 can be mounted to the individual semiconductor device die. A thermal reflow process forms solder joints between the bond pads on the passive component die (see, for example, 617 in FIG. 3C) and make physical attachment and electrical connections between the semiconductor device die 614 and the passive component die 631. After the passive component die and the semiconductor device die are combined, the combined elements are flip chip mounted to the package substrate as shown in FIGS. 6A-6C, again using a solder reflow process to form solder joints between the device mounting surface of the package substrate and the conductive post connects extending from the flip chip mounted semiconductor device die.

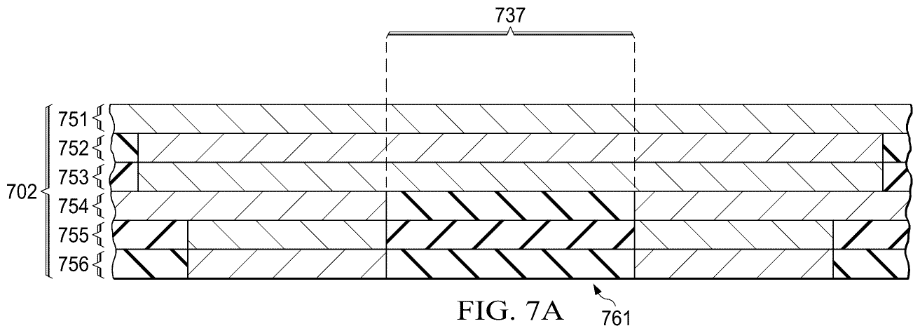

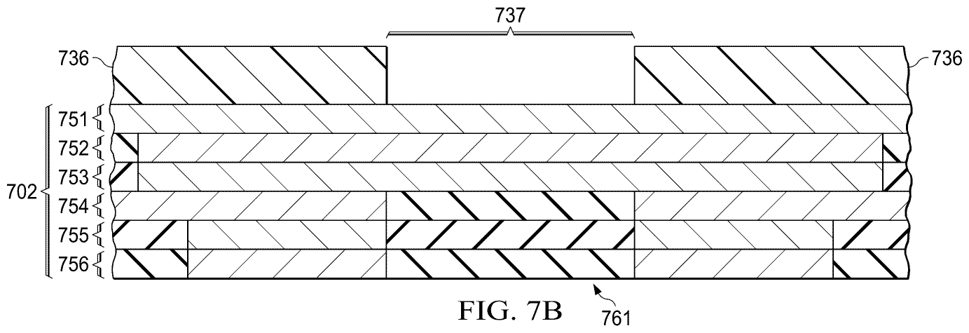

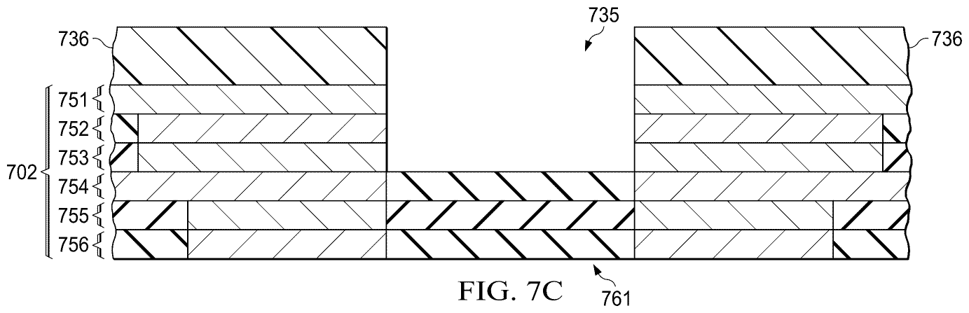

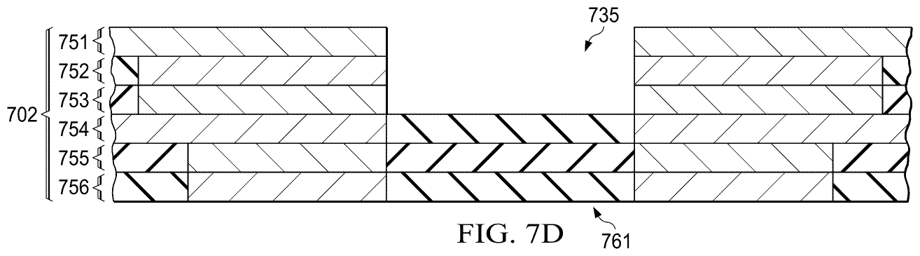

FIGS. 7A-7D illustrate, in a series of cross-sectional views, a process that is useful for forming the cavity in a multilayer package substrate used in the arrangements. In FIG. 7A, a multilayer package substrate 702, which is similar to the multilayer package substrate 602 shown in FIGS. 6A-6C, is shown with trace level conductor layers and vertical connection layers 751, 752, 753, 754, 755 and 756 in a dielectric material 761. The conductors in the layers are arranged to form a thick conductor structure over a dielectric layer in a cavity position 737. This position 737 corresponds to a passive component die location on a semiconductor device die to be mounted to the multilayer package substrate 702. In one example, the multilayer package substrate 702 can be formed using the additive build-up process shown in FIGS. 5A-5B, described above, and the dielectric 761 can be ABF, or another dielectric. The conductors can be copper or copper alloy, for example, or gold or another plated metal. In another example the package substrate can be premolded leadframe, or a leadframe.

FIG. 7B illustrates the multilayer package substrate 702 as shown in FIG. 7A, being readied for a metal etch process. In FIG. 7B, the cavity position 737 on the device side surface is defined by a photoresist mask layer 736 that is patterned in a photolithographic process to mask areas where metal etching is not desired, and to expose the conductor material in the cavity position 737 for processing.

FIG. 7C illustrates the multilayer package substrate 702 as shown in FIG. 7B after a cavity 735 has been formed in a metal etch process. Cavity 735 has vertical sides defined by the mask layer 736.

FIG. 7D illustrates in a further cross-sectional view the elements of FIG. 7C after the etch to form cavity 735 is complete. Photoresist layer 736 (see FIG. 7C) has been removed. The depth of the cavity 735 is configured to leave space for the passive component (see, for example 631 in FIGS. 6A-6C) to extend into the cavity, with room for mold compound (see, for example, mold compound 618 in FIG. 6A) to cover the passive component, the surfaces of the passive component are spaced from the vertical sides and the horizontal bottom of the cavity 735 when the flip chip elements of the semiconductor device die (see, for example, 614 in FIG. 6A) and the passive component die (see, for example 631 in FIG. 6A) are mounted to the package substrate.

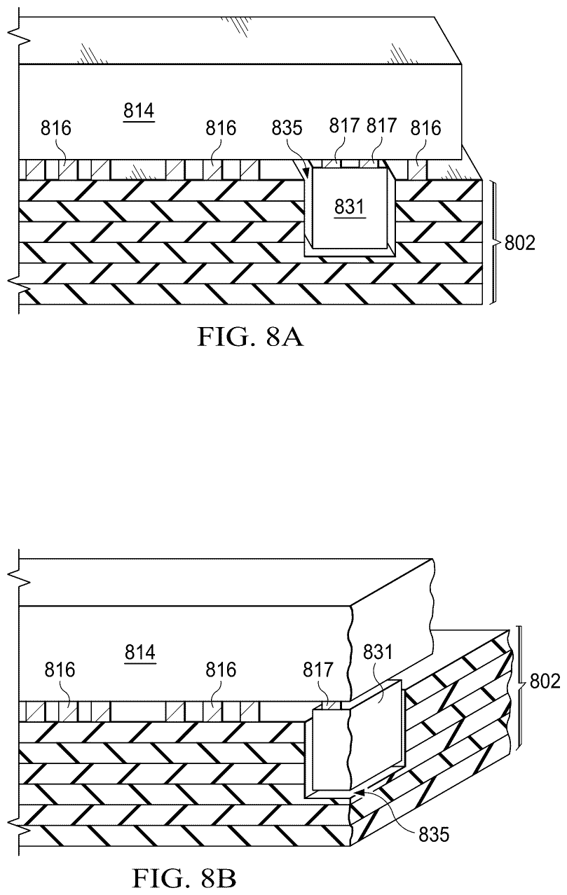

FIGS. 8A-8B illustrate, in partial cutaway views, details of an example arrangement using a multilayer package substrate with a cavity, and a passive component die mounted to a semiconductor device die that is flip chip mounted to the multilayer package substrate, with the passive component die extending into the cavity.

In FIG. 8A, a multilayer package substrate 802, which is similar to the multilayer package substrate 602 shown in FIGS. 6A-6C, is shown with trace level conductor layers and vertical connection layers in a dielectric material. Semiconductor device die 614 is shown flip chip mounted to a device mounting surface of the multilayer package substrate 802. The view in FIG. 8A taken with a cross section cut across cavity 835, to illustrate the details. The semiconductor device die 814 is coupled to and attached to the device mounting surface of the multilayer package substrate 802 by conductive post connects 816 using solder bumps (not shown) to form solder joints. The passive component die 631 is shown mounted to the device side surface of the semiconductor device die 814 by post connects 817 (again using solder bumps to form solder joints, not shown), the post connects 817 have less thickness than post connects 816. This thickness difference allows the passive component die 631 to extend a shorter distance into the cavity 835 in the multilayer package substrate 802, and thus allows the depth of the cavity 835 to be less, preserving more conductor layers beneath the cavity 835 for use in routing (when compared to another example, such as is illustrated in FIG. 6A, where the post connects are all of a common thickness). Note that in FIGS. 8A-8B, mold compound (see, for example mold compound 618 in FIG. 6A) is omitted for clarity of illustration, thus the passive component 831 is spaced from the sides and bottom of the cavity 835 in FIG. 8A. In an example process, the solder used for mounting the passive component die to the semiconductor device die can have a higher reflow temperature than the reflow temperature for solder used for flip chip mounting the semiconductor device die to the package substrate, so that after the passive component die is mounted in a first solder reflow operation, the second solder reflow operation to mount the combined elements to the package substrate does not adversely affect the mounted of the passive component die.

FIG. 8B illustrates in another cutaway view the elements of FIG. 8A with a cutaway showing the cross section of the passive component die 831 and a side of the passive component die 831, to show the passive component die 831 is extending lengthwise underneath semiconductor device die 814. Again in FIG. 8B, the mold compound is omitted so that the passive component 831 is spaced from the bottom of the cavity 835.

In the illustrated examples described above, the semiconductor device die, and the passive component die are combined by mounting the passive component die to the semiconductor device die, and then flip chip mounted to a device mounting surface of a multilayer package substrate. As shown in FIGS. 1A-1C and FIGS. 2A-2C, the multilayer package substrate can have terminals on a board side surface, and when the elements are overmolded with a mold compound, can form a QFN package.

In an alternative arrangement, the semiconductor device die, and the passive component die can be combined as described above, and then flip chip mounted on a leadframe, to form a QFN package with a leadframe as the package substrate. When a semiconductor die is flip chip mounted to a leadframe, this can be described as an “FCOL” or “flip chip on lead” package. One example of a thermally enhanced FCOL package that is provided as a QFN is referred to as an Enhanced Hot Rod QFN package, commercially available from Texas Instruments Incorporated of Dallas, Texas, USA. The Enhanced Hot Rod QFN package includes an exposed central thermal pad on a board side surface that is directly coupled to the semiconductor device die using pillars or columns, and thus provides a thermally conductive path to improve thermal dissipation at the board level. In an example arrangement, a cavity suitable for the passive component die of the combination of the semiconductor device die and the passive component die can be formed in a leadframe, and the combined devices can be flip chip mounted on the leadframe, including as one example in an Enhanced Hot Rod QFN package.

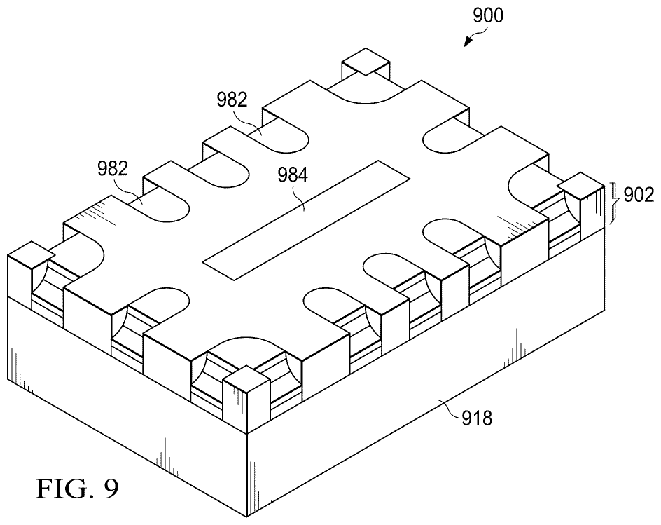

FIG. 9 illustrates, in a projection view, a board side surface of an Enhanced HotRod™ QFN package 900 that is useful with an arrangement. In FIG. 9, the board side surface of the QFN package 900 includes terminals 982 formed by leads of the leadframe (not visible in FIG. 9). Mold compound 918 covers the semiconductor device die and the passive component die mounted in the package. The leadframe forms package substrate 902, and in an example is a premolded leadframe. By forming a cavity (See, for example, cavity 635 in FIG. 6A) corresponding to the location of the passive component die before flip chip mounting the semiconductor device die to the leadframe, and then overmolding the leadframe and the components with mold compound, a robust QFN microelectronic device package is formed. The QFN package 900 includes a thermal pad 984 in a central portion of the board side surface. The thermal pad 984 can be coupled with the semiconductor device die using several conductive post connects that are coupled to a ground terminal or terminals of the semiconductor device die, for example, to provide thermal dissipation from the semiconductor device die within the QFN package 900.

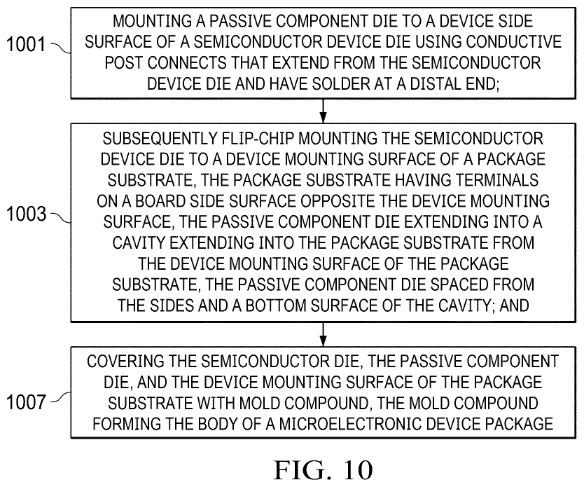

FIG. 10 is a process flow diagram of an example process for forming an arrangement. The process begins at step 1001, by mounting a passive component die to a device side surface of a semiconductor device die using conductive post connects that extend from the semiconductor device die and have solder at a distal end. (See, for example, FIGS. 6A-6D, the plan view of FIG. 6D shows the passive component die 631 mounted to the device side surface of the semiconductor device die 614).

At step 1003, the process continues by subsequently flip chip mounting the semiconductor device die to a device mounting surface of a package substrate, the package substrate having terminals on a board side surface opposite the device mounting surface, the passive component die extending into a cavity extending into the package substrate from the device mounting surface of the package substrate, the passive component die spaced from the sides and a bottom surface of the cavity. (See, for example, the cross-sectional views of FIGS. 6A-6C, showing the passive component die 631 in the cavity 635 of the package substrate 602, with the semiconductor device die 614 mounted to the surface. FIGS. 7A-7D illustrate a method for forming the cavity in a multilayer package substrate by use of photolithography and metal etch processes.)

The process completes at step 1007, by covering the semiconductor device die, the passive component die, and the device mounting surface of the package substrate with mold compound, the mold compound forming the body of a microelectronic device package. (See, for example, mold compound 618 in FIG. 6A).

In the illustrated examples, a passive component die is mounted to a device side surface of a semiconductor device die, which is then subsequently flip chip mounted to a package substrate. As described above, a cavity is formed in the package substrate that allows the passive component die to extend into the cavity, enabling the flip chip mounting of the combined components. In one example, the passive component die can be a semiconductor trench capacitor. In a particular example, the semiconductor trench capacitor is coupled to power and ground terminals of the semiconductor device die as a bypass capacitor. However, in alternative arrangements, the semiconductor trench capacitor can be coupled as an input capacitor between input terminals and ground, for example, to filter noise. Because the passive component die is directly connected to the semiconductor device die without trace conductors, loop inductance that is formed in prior approach packages is reduced or eliminated, allowing for smaller capacitor values to be used.

In additional alternative arrangements, the passive component die can be another component type formed in a die, such as a resistor, inductor, diode, or sensor device. In further alternative arrangements, multiple cavities can be formed in the package substrate, and multiple passive component dies can be mounted beneath the semiconductor device die. Use of the arrangements enables greater integration in a system-in-package microelectronics device package than can be attained in a prior approach without use of the arrangements. Advantageously, in the arrangements, the passive component dies are placed beneath the semiconductor device die, so that no additional area is needed on the package substrate to mount these devices.

In the illustrated example, multilayer package substrates are used, and in particular examples, build-up multilayer package substrates are described. However, in additional alternative arrangements, package substrates including leadframes, partially etched leadframes, premolded leadframes (PMLFs), and molded interconnect substrates (MIS) can be used. In the arrangements, the package substrate has a cavity extending into a device mounting surface of the package substrate of sufficient depth and width that when a semiconductor device die and a passive component die mounted to the semiconductor device die can be flip chip mounted onto the package substrate, the passive component die extends into the cavity, while remaining spaced from the sides and bottom of the cavity. Use of the arrangements provides advantages in system performance and increased integration, while using existing packaging processes and tools, so that implementation of the arrangements is cost effective and easily achieved.

The use of the arrangements provides a microelectronic device package with a semiconductor device die and a passive component die combined, and flip chip mounted to a package substrate. Existing materials and assembly tools are used to form the arrangements. The arrangements are formed using existing methods, materials, and tooling for making the devices and are cost effective.

Modifications are possible in the described examples, and other examples are possible, within the scope of the claims.

What is claimed is:

1. An apparatus, comprising:
a passive component die mounted to a device side surface of a semiconductor device die, and extending away from the device side surface of the semiconductor device die;
the semiconductor device die and the passive component die flip chip mounted to a device mounting surface of a package substrate including a cavity extending into the package substrate from the device mounting surface of the package substrate, the cavity in a position corresponding to the passive component die, the passive component die extending into the cavity of the package substrate, and the package substrate having terminals on a board side surface; and
mold compound covering the semiconductor device die, the passive component die, and the device mounting surface of the package substrate, the mold compound forming the body of a microelectronic device package, the terminals of the package substrate forming terminals of the microelectronic device package.

2. The apparatus of claim 1, wherein the package substrate further comprises a multilayer package substrate having trace level conductors spaced from one another by dielectric material, and vertical connection layer conductors extending through the dielectric material between the trace level conductors to selectively connect the trace level conductors.

3. The apparatus of claim 2, wherein the multilayer package substrate comprises a build-up package substrate including plated trace level conductors spaced by the dielectric material, and plated vertical connection layers extending through the dielectric material between the plated trace level conductor layers, and wherein the dielectric material comprises Ajinomoto Build-Up Film.

4. The apparatus of claim 1, wherein the package substrate further comprises one of a leadframe, a partially etched leadframe, a premolded leadframe, or a molded interconnect substrate.

5. The apparatus of claim 1, wherein the passive component die is one of a capacitor, a resistor, an inductor, a coil, a diode, or a sensor.

6. The apparatus of claim 1, wherein the passive component die is a semiconductor trench capacitor.

7. The apparatus of claim 6, wherein the passive component die is a silicon trench capacitor.

8. The apparatus of claim 7, wherein the passive component die is a semiconductor trench capacitor that is coupled to the semiconductor device die as a bypass capacitor between a power terminal and a ground terminal of the semiconductor device die.

9. The apparatus of claim 1, wherein the passive component die overlies a portion of the device side surface of the semiconductor die and is mounted to the device side surface of the semiconductor device die using a first set of conductive post connects extending from bond pads on the semiconductor device die including solder on a distal end, and the semiconductor die is flip chip mounted to the device mounting surface of the package substrate using a second set of conductive post connects including solder on a distal end that are spaced from the passive component die.

10. The apparatus of claim 9, wherein the first set of conductive post connects used to mount the passive component die to the semiconductor device die have a first thickness that is less than a second thickness for the second set of conductive post connects.

11. The apparatus of claim 1, wherein the passive component die is mounted to the semiconductor device die by depopulating conductive post connects on the device side surface of the semiconductor device die in an area where the passive component die is mounted, and the passive component die is mounted using additional conductive post connects configured for mounting the passive component die on the device side surface of the semiconductor device die.

12. The apparatus of claim 1, wherein the microelectronic device package is a quad flat no-lead (QFN) package.

13. The apparatus of claim 1, wherein the package substrate is a leadframe and the microelectronic device package is a flip chip on lead package.

14. A microelectronic device package, comprising:
a semiconductor trench capacitor die mounted to a device side surface of a semiconductor device die using conductive post connects extending from bond pads on the semiconductor device die and including solder on a distal end, the mounted semiconductor trench capacitor die extending away from the device side surface of the semiconductor device die;
the semiconductor device die and the semiconductor trench capacitor die flip chip mounted to a device mounting surface of a package substrate, the package substrate including a cavity extending into the package substrate from the device mounting surface, the cavity in a position corresponding to the semiconductor trench capacitor die that extends into the cavity of the package substrate, and the package substrate including terminals on a board side surface; and
mold compound covering the semiconductor device die, the semiconductor trench capacitor die and the device mounting surface of the package substrate, the mold compound filling space in the cavity around the trench capacitor semiconductor die, the mold compound forming the body of the microelectronic device package, the terminals of the package substrate forming terminals of the microelectronic device package.

15. The microelectronic device package of claim 14, wherein the package substrate comprises a multilayer package substrate including trace level conductors in layers spaced by dielectric material, and vertical connection layer conductors extending through the dielectric material and connecting the trace level conductors.

16. The microelectronic device package of claim 15, wherein the multilayer package substrate is a build-up multilayer package substrate, and the dielectric material is Ajinomoto Build-Up Film.

17. The microelectronic device package of claim 14, wherein the package substrate is one of a leadframe, a partially etched leadframe, a premolded leadframe, or a molded interconnect substrate.

18. The microelectronic device package of claim 14, wherein the semiconductor trench capacitor die is a semiconductor trench capacitor coupled to the semiconductor device die as a bypass capacitor between a power terminal and a ground terminal of the semiconductor device die.

19. The microelectronic device package of claim 14, wherein the mounted semiconductor trench capacitor die overlies a portion of the device side surface of the semiconductor device die and is mounted by the conductive post connects that form a first set of conductive post connects, and the semiconductor device die is flip chip mounted to the device mounting surface of the package substrate using as second set of conductive post connects that extend from bond pads on the semiconductor device die including solder on a distal end and which are spaced from the passive component die.

20. The microelectronic device package of claim 19, wherein the first set of conductive post connects used to mount the semiconductor trench capacitor die to the semiconductor device die has a first bump height that is less than a second bump height for the second set of conductive post connects.

21. The apparatus of claim 14, wherein the passive component die is mounted to the semiconductor device die by depopulating conductive post connects on the device side surface of the semiconductor device die in an area where the passive component die is mounted, and the passive component die is mounted to additional conductive post connects that are placed on the device side surface of the semiconductor die and configured for mounting the passive component die on the device side surface of the semiconductor die.

22. The microelectronic device package of claim 14, wherein the microelectronic device package is a quad flat no-lead (QFN) package.

23. The microelectronic device package of claim 14, wherein the package substrate is a leadframe and the microelectronic device package is a flip chip on lead package.

24. A method comprising:
forming a cavity in a device mounting surface of a package substrate, the package substrate including a board side surface opposite the device side surface;
mounting a passive component die to a device side surface of a semiconductor device die using conductive post connects that extend from bond pads on device side surface of the semiconductor device die and that include solder at a distal end;
subsequently flip chip mounting the semiconductor device die to the device mounting surface of the package substrate using additional conductive post connects that extend from bond pads on the device side surface of the semiconductor device die and which include solder on a distal end, the package substrate having terminals on a board side surface opposite the device mounting surface, the passive component die extending into the cavity from the device mounting surface of the package substrate, the passive component die spaced from sides and a bottom surface of the cavity; and
covering the semiconductor device die, the passive component die, and the device mounting surface of the package substrate with mold compound, the mold compound forming the body of a microelectronic device package.

25. The method of claim 24, wherein forming the cavity in the package substrate comprises patterning trace level conductors and vertical connection layer conductors in the package substrate to form a conductor structure extending into the package substrate from the device mounting surface, and subsequently performing an etch to remove the conductor structure from the device mounting surface to form the cavity extending into the package substrate, forming the cavity at a location corresponding to a position of the passive component die.

26. The method of claim 24 wherein mounting the passive component die further comprises depopulating conductive post connects from a device side surface of the semiconductor device die in an area where the passive component die is to be mounted, placing additional conductive post connects having solder on the distal ends extending from bond pads on the device side surface of the semiconductor device die, and mounting the passive component to the semiconductor device die using the additional conductive post connects.

27. The method of claim 24, wherein flip chip mounting the semiconductor device die to a device mounting surface of the package substrate further comprises: forming solder joints between conductive lands on the device mounting side of the package substrate and solder bumps disposed on distal ends of conductive post connects that extend from bond pads on the semiconductor device die.

28. The method of claim 27, wherein mounting the passive component die to the device side surface of the semiconductor device die further comprises: positioning the passive component die to contact the solder on the distal ends of conductive post connects configured for mounting the passive component die, performing a thermal reflow of solder bumps at a first temperature, and wherein flip chip mounting the semiconductor die to a device side surface of the package substrate further comprises subsequently performing thermal reflow of solder at the distal ends of additional conductive post connects at a second temperature that is lower than the first temperature.

29. The method of claim 24, wherein the package substrate comprises a build-up multilayer package substrate with dielectric material between layers of trace level conductors, and the dielectric material is Ajinomoto Build-up Film.
